(19) United States
(12) Patent Application Publication
(10) Pub. No.: US 2014/0184261 A1
(43) Pub. Date: Jul. 3, 2014

(54) TESTING APPARATUS AND TESTING METHOD

(71) Applicant: Siliconware Precision Industries Co., Ltd., Taichung (TW)

(72) Inventors: Chia-Chu Lai, Taichung (TW); Ming-Fan Tsai, Taichung (TW); Ho-Chuan Lin, Taichung (TW); Min-Han Chuang, Taichung (TW); Bo-Shiang Fang, Taichung (TW)

(73) Assignee: SILICONWARE PRECISION INDUSTRIES CO., LTD., Taichung (TW)

(21) Appl. No.: 14/056,214

(22) Filed: Oct. 17, 2013

(30) Foreign Application Priority Data
Jan. 3, 2013 (TW) 102100083

(51) Int. Cl. G01R 1/04

(52) U.S. Cl. CPC G01R 1/0491
USPC 324/756.07

(57) ABSTRACT

A testing method is provided, including providing a testing apparatus including a carrier member and a testing element, the carrier member comprising a first surface, a second surface opposing the first surface, and an elastic conductive area defined on the first surface; disposing an object-to-be-tested on the elastic conductive area; electrically connecting the testing element to the object-to-be-tested and the carrier member, to form an electric loop among the carrier member, the object-to-be-tested and the testing element. Through the design of the elastic conductive area, the object-to-be-tested can be secured with a small pressure applied thereto, and is prevented from being cracked.

### BACKGROUND OF THE INVENTION

1. Field of the Invention

This invention relates to testing apparatuses and testing methods, and, more particularly, to a testing apparatus and a testing method for testing a semiconductor element.

2. Description of Related Art

With the rapid development of electronic technology, electronic products are required to be compact-sized and low-profiled. As semiconductor fabrication techniques gain significant progresses, more electronic components can be disposed within a limited area of a chip, and an electronic product, in which the chip is installed, can thus have a variety of functions. One of the progresses is the introduction of a stack technique, whereby a plurality of chips are stacked on a substrate to form a 3-D integrated circuit (3D IC) semiconductor package.

In an IC semiconductor package, a plurality of chips that have different functions, quality or substrates are fabricated separately by suitable processes, and stacked on one another by a through-silicon via (TSV) technique, such that the length of a conduction path is shortened, a “turn-on” resistance is reduced, and the chip area is decreased. A semiconductor package (2.5D IC) thus fabricated has the advantages of small volume, high integrity, high efficiency, low power consumption and low cost, and meets the compact-sized and low-profiled requirements.

In the 2.5D IC fabrication process, a chip probe process has to be performed before the stacked chips are packaged, in order to filter out any defective chips, which affect the yield of the electronic product.

As shown in FIGS. 1A and 1B, the chip probe process is performed on a wafer substrate 9 having a through silicon via 90 that is ready to be combined with a chip 8. In the chip probe process, an object-to-be-tested 7 (i.e., the chip 8 and the wafer substrate 9 having the through silicon via 90) is placed on a testing apparatus 1 that has a base 10 and an upper cover 11, and the base 10, the object-to-be-tested 7 and the upper cover 11 are adhered to one another closely by air pressure, such that a PogoPin 110 of the upper cover 11 is electrically connected to electric contacts 91 disposed on an upper side of the wafer substrate 9, and traces 100 and conductive bumps 101 of the base 10 are electrically connected to electric contacts 92 disposed on a lower side of the wafer substrate 9. Another PogoPin (not shown) is then in contact with the conductive bumps 101, so as to form a dual-sided (upper and lower sides L1 and L2) probing circuit loop.

In general, the wafer substrate 9 having through silicon via 90 is thin (e.g., 10 to 180 ∥m in thickness), and is likely to be cracked as the PogoPin 110 presses downward during the wafer probe process.

Besides, since the wafer substrate 9 is not fixed to the base 10 securely, the wafer substrate 9 is likely to be damaged when the air pressure is applied thereto.

Moreover, in the testing apparatus 1 since the air pressure cannot provide an accurate alignment, the dual-sided probing circuit loop L1 and L2 formed by the object-to-be-tested 7 and the testing apparatus 1 will suffer from a misalignment problem. Therefore, how to solve the problems is becoming an urgent issue in the art.

### SUMMARY OF THE INVENTION

In view of the above-mentioned problems of the prior art, the present invention provides a testing apparatus, comprising: a carrier member having a first surface, a second surface opposing the first surface, and an elastic conductive area defined on the first surface for at least one object-to-be-tested to be disposed thereon; and a testing element for being electrically connected to the elastic conductive area when the object-to-be-tested is tested.

The present invention further provides a testing method, comprising: providing a testing apparatus including a carrier member and a testing element, the carrier member comprising a first surface, a second surface opposing the first surface, and an elastic conductive area defined on the first surface; disposing an object-to-be-tested on the elastic conductive area; and electrically connecting the testing element to the object-to-be-tested and the carrier member, to form an electric loop among the carrier member, the object-to-be-tested and the testing element.

In an embodiment, the testing element is in contact with the object-to-be-tested so as to be electrically connected to the object-to-be-tested.

In an embodiment, the carrier member is electrically connected to the testing element via a trace.

In an embodiment, the carrier member comprises an annular base and a conductive layer formed on the annular base and having one side that acts as the elastic conductive area, and the annular base has a positioning portion for the conductive layer to be disposed thereon. In an embodiment, the positioning portion is a stepped structure disposed on an inner annular surface of the annular base.

In an embodiment, the carrier member comprises a plate base and a conductive layer formed on the plate base.

In an embodiment, the conductive layer comprises a conductive material having an adhesive function.

In an embodiment, the testing element has a probe portion electrically connected to the object-to-be-tested. The probe portion is electrically connected to the object-to-be-tested by contacting itself with the object-to-be-tested.

According to the testing apparatus and the testing method of the present invention, the object-to-be-tested can be fixed securely with a small pressure due to the design of the elastic conductive area, and can be prevented from being cracked. Since the elastic conductive area is a complete surface of a conductive body, all of electric contacts will still be in contact with the elastic conductive area even if the object-to-be-tested is not aligned with the electric contacts accurately. The misalignment problem of the problem in the prior art is thus solved.

If the electric contacts of the object-to-be-tested are not in the same height, the taller ones of the electric contacts can be inserted into the elastic conductive area while the shorter ones can be in contact with the elastic conductive area with a small pressure applied downward. Therefore, all of the electric contacts can be in contact with the elastic conductive area, so as to ensure the stable quality of electrical connection.

### BRIEF DESCRIPTION OF DRAWINGS

The invention can be more fully understood by reading the following detailed description of the preferred embodiments, with reference made to the accompanying drawings, wherein:

FIGS. 1A and 1B are side views illustrating a testing method of a testing apparatus and an object-to-be-tested according to the prior art;

FIG. 2A is a side view of a testing apparatus of an embodiment according to the present invention;

FIG. 2A′ is an exploded view of a carrier member of the testing apparatus shown in FIG. 2A′;

FIG. 2B is a side view illustrating a testing method according to the present invention;

FIG. 2B′ is an enlarged view of a portion of FIG. 2B; and

FIG. 3 is a side view of a test apparatus of another embodiment according to the present invention.

### DETAILED DESCRIPTION OF THE INVENTION

The following illustrative embodiments are provided to illustrate the disclosure of the present invention, these and other advantages and effects can be apparently understood by those in the art after reading the disclosure of this specification. The present invention can also be performed or applied by other different embodiments. The details of the specification may be on the basis of different points and applications, and numerous modifications and variations can be devised without departing from the spirit of the present invention.

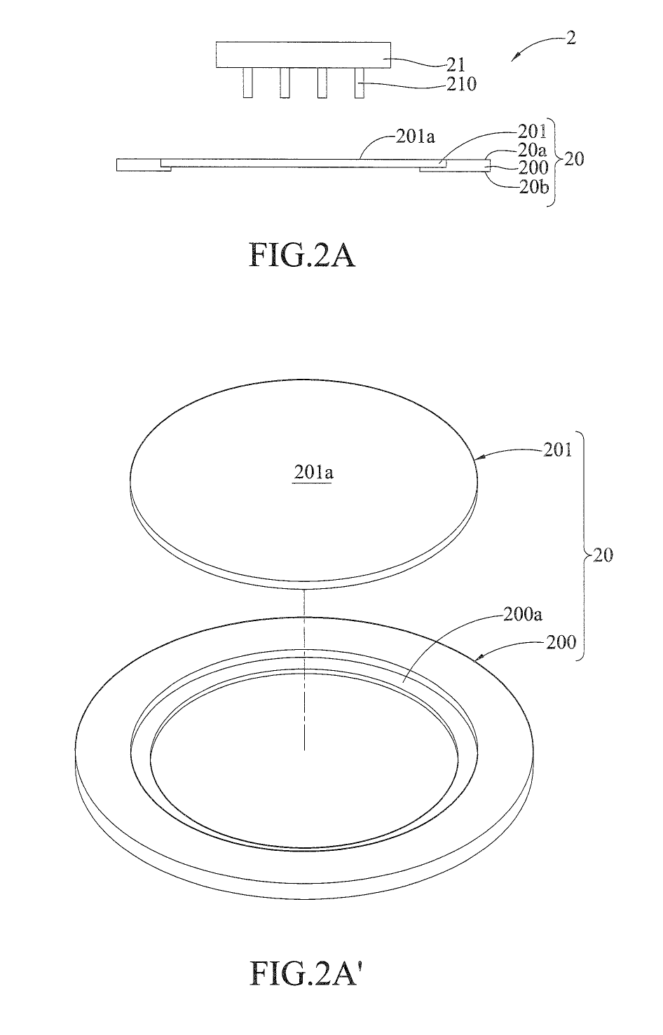

FIGS. 2A and 2B are schematic diagrams of a testing apparatus 2 of an embodiment according to the present invention. The testing apparatus 2 comprises a carrier member 20 and a testing element 21.

The carrier member 20 has a first surface 20a, a second surface 20b opposing the first surface 20a, and an elastic conductive area 201a defined on the first surface 20a.

In an embodiment, the carrier member 20 comprises an annular base 200 and a conductive layer 201 formed in the annular base 200 and having an upper side that acts as the elastic conductive area 201a.

In an embodiment, the annular base 200 has a positioning portion 200a for the conductive layer 201 to be disposed thereon. In another embodiment, the positioning portion 200a is a stepped structure disposed on the inner annular surface of the annular base 200. In yet another embodiment, the positioning portion has a concave-convex structure or a pillar structure.

In an embodiment, the conductive layer 201 is a conductive colloid or a conductive film (e.g., a metal film), and is made of a conductive material having an adhesive function, such as conductive epoxy resin or colloidal silver.

In an embodiment, the testing element 21 has a probe portion 210. In another embodiment, the testing element 21 is a probe card, and has disposed therein a current generator (not shown), an amplifier circuit (not shown), a comparator circuit (not shown), and an LED lamp (not shown) that electrically conducts the comparator circuit.

In the testing apparatus 2, the testing element 21 is electrically via a trace 22 (as shown in FIG. 2B) to the carrier member 20, so as to form a conductive loop.

FIG. 2B is a side view illustrating a testing method by using the testing apparatus 2 according to the present invention.

In the testing method, at least one object-to-be-tested 3 is placed on the elastic conductive area 201a and is electrically connected via the conductive layer 201 to the annular base 200. Then, the probe portion 210 is in contact with the object-to-be-tested 3, allowing the testing element 21 to be electrically connected to the object-to-be-tested 3 and at least one trace 22 to electrically connect the annular base 200 to the testing element 21. As a result, the elastic conductive area 201a, the object-to-be-tested 3 and the testing element 21 form an electric loop, for an electric test to be performed sequentially.

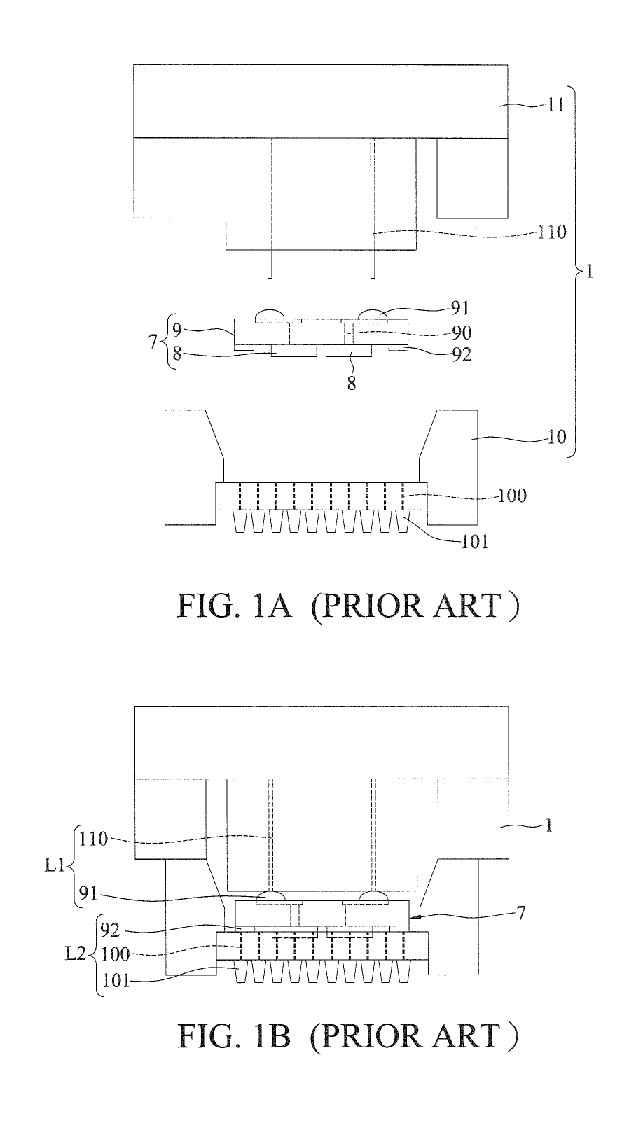

In an embodiment, the object-to-be-tested 3 is an interposer having a through silicon via 30, and is sized the same as a die or a wafer. In another embodiment, a redistribution layer 33 is formed on an upper side and a bottom side of the object-to-be-tested 3, and a plurality of first conductive bumps 31 and second conductive bumps 32 that act as electric contacts are disposed on the redistribution layer 33 formed on the upper side and the bottom side, respectively, allowing the probe portion 210 to be in contact with the first conductive bumps 31, and the second conductive bumps 32 to be in contact with the elastic conductive area 201a. In yet another embodiment, the object-to-be-tested 3 can have other structures or can be other electronic components (e.g., the object-to-be-tested 7 shown in FIG. 1A).

In an embodiment, at least one of the first conductive bumps 31 is 80 um in diameter and 75 um in height, two of the first conductive bumps 31 are spaced apart at 150 um, at least one of the second conductive bumps 32 is 80 um in diameter, and two of the second conductive bumps 32 are spaced apart at 250 um.

In an electric test process, the through silicon via 30 of the object-to-be-tested 3 acts as a resistor. The current generator of the testing element 21 generates a current flowing through the probe portion 210 to the through silicon via 30 of the object-to-be-tested 3, and provides a voltage to the amplifier circuit of the testing element 21. The amplifier circuit amplifies the voltage and transfers the amplified voltage to the comparator circuit of the testing element 21. The comparator circuit compares the amplified voltage with reference data embedded in the comparator circuit, and transfers a comparison signal to the LED lamp of the testing element 21. The LED lamp, if blinking, indicates that the through silicon via 30 is well conductive.

The carrier member 20 can cooperate with a die pick-and-place machine, and place the object-to-be-tested 3 in the testing apparatus 2 automatically, in order to enhance the fabrication efficiency and reduce the cost.

In a testing method according to the present invention, through the design of the elastic conductive area 201a a small pressure is enough to fix the object-to-be-tested 3 between the testing element 21 and the carrier member 20, preventing the object-to-be-tested 3 from being cracked. The elastic conductive area 201a can buffer a force applied to the testing element 21, which can further prevent the object-to-be-tested 3 from being cracked.

If the elastic conductive area 201a is made of a colloidal material, a tiny pressure is enough to fix the object-to-be-tested 3, thus preventing the object-to-be-tested 3 from being cracked.

Since the elastic conductive area 201a is a complete surface of a conductive body, the second conductive bumps 32 do not suffer from the misalignment problem. Therefore, the second conductive bumps 32, even if being offset, can be still in contact with the elastic conductive area 201a completely and operate in a conductive state.

As shown in FIG. 2B′, if the second conductive bumps 32, 32′ are not equal in height, a small downward pressure can still make all of the second conductive bumps 32, 32′ to be in contact with the elastic conductive area 201a. In this scenario, the taller ones of the second conductive bumps 32′ are inserted into the elastic conductive area 201a, while the shorter ones are in contact with a surface of the elastic conductive area 201a, so as to keep the quality of electric connection stable.

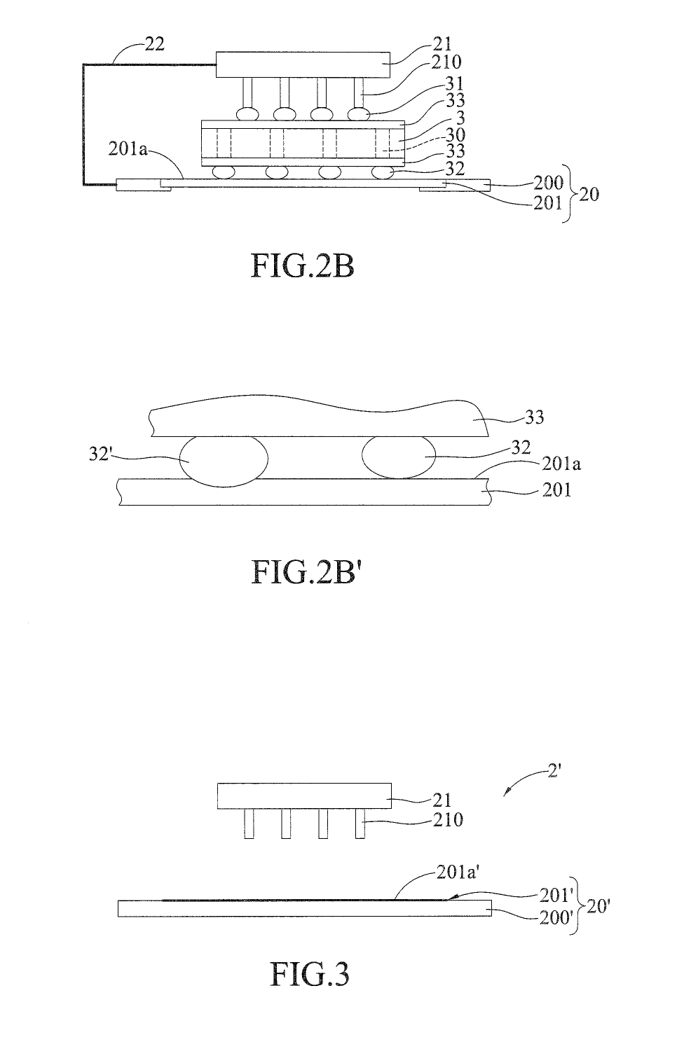

FIG. 3 is side view of a testing apparatus 2′ of another embodiment according to the present invention, The testing apparatus 2′ differs from the testing apparatus in the structure of a carrier member 20′.

In an embodiment, the carrier member 20′ comprises a plate base 200′ and a conductive layer 201′ formed on the plate base 200′. In another embodiment, the conductive layer 201′ is a film adhered to the plate base 200′, so as to form on a surface of the plate base 200′ an elastic conductive area 201 a′.

In a testing apparatus and a testing method according to the present invention, through the design of an elastic conductive area a small pressure is enough to fix an the object-to-be-tested. Therefore, the object-to-be-tested is prevented to be cracked, and the problem of the prior art that the electric test is affected due to misalignment is solved.

If the electric contacts of the object-to-be-tested are not equal in height, the taller ones of the electric contacts can be inserted into the elastic conductive area, while the shorter ones can be in contact with the elastic conductive area, such that the electric connection can have stable quality.

According to the present invention, a testing apparatus can be fixed and electrically connected to an object-to-be-tested, without an additional fixture. Therefore, the size and shape of the object-to-be-tested will not limit the application of the testing apparatus. Accordingly, a testing method according to the present invention can be applied not only to the chip probe process performed before a packaging process, but also to other function testing processes performed after the packaging process, and is thus highly flexible

The foregoing descriptions of the detailed embodiments are only illustrated to disclose the features and functions of the present invention and not restrictive of the scope of the present invention. It should be understood to those in the art that all modifications and variations according to the spirit and principle in the disclosure of the present invention should fall within the scope of the appended claims.

What is claimed is:

1. A testing apparatus, comprising:
a carrier member having a first surface, a second surface opposing the first surface, and an elastic conductive area defined on the first surface for at least one object-to-be-tested to be disposed thereon; and
a testing element for being electrically connected to the elastic conductive area when the object-to-be-tested is tested.

2. The testing apparatus of claim 1, wherein the carrier member comprises an annular base and a conductive layer formed in the annular base having one side that acts as the elastic conductive area.

3. The testing apparatus of claim 2, wherein the conductive layer is made of a conductive material having an adhesive function.

4. The testing apparatus of claim 2, wherein the annular base has a positioning portion for the conductive layer to be disposed thereon.

5. The testing apparatus of claim 4, wherein the positioning portion is a stepped structure disposed on an inner annular surface of the annular base.

6. The testing apparatus of claim 1, wherein the carrier member comprises a plate base and a conductive layer formed on the plate base.

7. The testing apparatus of claim 6, wherein the conductive layer comprises a conductive material having an adhesive function.

8. The testing apparatus of claim 1, wherein the testing element includes a probe portion for being electrically connected to the object-to-be-tested.

9. The testing apparatus of claim 1, further comprising a trace electrically connected between the carrier member and the testing element.

10. A testing method, comprising:
providing a testing apparatus including a carrier member and a testing element, the carrier member comprising a first surface, a second surface opposing the first surface, and an elastic conductive area defined on the first surface;
disposing an object-to-be-tested on the elastic conductive area; and
electrically connecting the testing element to the object-to-be-tested and the carrier member, to form an electric loop among the carrier member, the object-to-be-tested and the testing element.

11. The testing method of claim 10, wherein the carrier member comprises an annular base and a conductive layer formed in the annular base and having one side that acts as the elastic conductive area.

12. The testing method of claim 11, wherein the conductive layer comprises a conductive material having an adhesive function.

13. The testing method of claim 11, wherein the annular base includes a positioning portion for the conductive layer to be disposed thereon.

14. The testing method of claim 13, wherein the positioning portion is a stepped structure disposed on an inner annular surface of the annular base.

15. The testing method of claim 10, wherein the carrier member comprises a plate base and a conductive layer formed on the plate base.

16. The testing method of claim 15, wherein the conductive layer comprises a conductive material having an adhesive function.

17. The testing method of claim 10, wherein the testing element has a probe portion for being connected to the object-to-be-tested.

18. The testing method of claim 17, wherein electrically connecting the testing element to the object-to-be-tested comprises contacting the object-to-be-tested with the probe portion.

19. The testing method of claim 10, wherein electrically connecting the testing element to the object-to-be-tested comprises contacting the object-to-be-tested with the testing element.

20. The testing method of claim 10, wherein the carrier member is electrically connected to the testing element by a trace.
